(19) United States
(12) Patent Application Publication
(10) Pub. No.: US 2025/0311649 A1
(43) Pub. Date: Oct. 2, 2025

(54) METHOD OF MANUFACTURING GAMMA-GESE LAYER AND METHOD OF MANUFACTURING MEMORY DEVICE BY USING THE SAME

(71) Applicants: Samsung Electronics Co., Ltd., Suwon-si (KR); UIF (University Industry Foundation), Yonsei University, Seoul (KR)

(72) Inventors: Kwanpyo KIM, Seoul-si (KR); Sol LEE, Seoul-si (KR); Joong-Eon JUNG, Seoul-si (KR)

(73) Assignees: Samsung Electronics Co., Ltd., Suwon-si (KR); UIF (University Industry Foundation), Yonsei University, Seoul (KR)

(21) Appl. No.: 18/977,239

(22) Filed: Dec. 11, 2024

(30) Foreign Application Priority Data
Apr. 2, 2024 (KR) 10-2024-0044933

(51) Int. Cl. H10N 70/00; H10B 63/10; H10N 70/20

(52) U.S. Cl. CPC H10N 70/8825; H10B 63/10; H10N 70/021; H10N 70/235; H10N 70/8613

(57) ABSTRACT

A method of manufacturing a gamma-germanium selenide (γ-GeSe) layer may include coating a first surface of a base layer with a catalytic metal, providing alpha-germanium selenide (α-GeSe) at a first position in a processing space and providing the base layer at a second position in the process space, which is spaced apart from the first position in the processing space, heating the first position in the processing space to a first temperature, supplying gas from the first position to the second position in the processing space, and depositing γ-GeSe on the first surface of the base layer. The base layer may include a crystalline material having a crystal system that is hexagonal.

### CROSS-REFERENCE TO RELATED APPLICATION

This application claims priority under 35 U.S.C. § 119 to Korean Patent Application No. 10-2024-0044933, filed on Apr. 2, 2024, in the Korean Intellectual Property Office, the disclosure of which is incorporated by reference herein in its entirety.

### BACKGROUND

Inventive concepts relate to a method of manufacturing a gamma-germanium selenide (GeSe) layer and a method of manufacturing a memory device by using the same.

GeSe has several polymorphs depending on the atomic structure. Although alpha-GeSe is generally common and has been studied a lot, synthesis of gamma-GeSe with the same elemental composition ratios but different structures and properties has recently been reported.

### SUMMARY

Inventive concepts provide a method of manufacturing a gamma-germanium selenide (GeSe) layer having improved yield and purity.

Inventive concepts provide a method of manufacturing a gamma-GeSe layer having improved coverage.

Inventive concepts provide a method of manufacturing a memory device with improved efficiency of the manufacturing method.

Aspects of inventive concepts are not limited to the above-mentioned task, and other aspects not mentioned may be clearly understood by those of ordinary skill in the art from the following description.

According to an embodiment of inventive concepts, a method of manufacturing a gamma-germanium selenide (γ-GeSe) layer may include coating a first surface of a base layer with a catalytic metal; providing alpha-germanium selenide (α-GeSe) at a first position in a processing space, and providing the base layer at a second position spaced apart from the first position in the processing space, the second position in the processing space being spaced apart from the first position in the processing space; heating the first position in the processing space to a first temperature; supplying gas from the first position in the processing space to the second position in the processing space; and depositing γ-GeSe on the first surface of the base layer. The base layer may include a crystalline material having a crystal system that may be hexagonal.

According to an embodiment of inventive concepts, a method of manufacturing a gamma-germanium selenide (γ-GeSe) layer may include coating a first surface of a base layer with a catalytic metal; providing alpha phase GeSe at a first position in a cylindrical processing space and providing the base layer at a second position in the cylindrical processing space, the second position in the cylindrical processing space being spaced apart from the first position in the cylindrical processing space; vaporizing the alpha phase GeSe into vaporized GeSe by heating the first position of the cylindrical processing space to a first temperature; supplying the vaporized GeSe from the first position of the cylindrical processing space to the second position of the cylindrical processing space in of the cylindrical processing space; and depositing gamma-phase GeSe on the first surface of the base layer. A crystal system of the gamma-phase GeSe may be same as a crystal system of a crystalline material in the base layer.

According to an embodiment of inventive concepts, a method of manufacturing a memory device may include forming word lines on a substrate; forming memory cells on the word lines; forming an insulating layer between the memory cells; and forming a bit line on each of the memory cells. Each of the memory cells may include a lower electrode, a switch layer, an intermediate electrode, a phase change layer, and an upper electrode, which may be sequentially stacked. The phase change layer may include a gamma-GeSe (γ-GeSe) layer. The forming the memory cells on the word lines may include forming the γ-GeSe layer through a process including coating a first surface of a base layer with a catalytic metal, providing alpha-GeSe (α-GeSe) at a first position in a cylindrical processing space and providing the base layer at a second position in the processing space, the second position in the cylindrical processing space being spaced apart from the first position in the cylindrical processing space, heating the first position in the cylindrical processing space to a first temperature and heating the second position in the cylindrical processing space to a second temperature, the second temperature being lower than the first temperature, supplying gas from the first position in the cylindrical processing space to the second position in the cylindrical processing space, and depositing γ-GeSe on the first surface of the base layer. The base layer may include a crystalline material having a crystal system that may be hexagonal.

### BRIEF DESCRIPTION OF THE DRAWINGS

Embodiments of inventive concepts will be more clearly understood from the following detailed description taken in conjunction with the accompanying drawings in which:

FIG. 1 is a flowchart illustrating a method of manufacturing a gamma-germanium selenide (GeSe) layer, according to an embodiment;

FIG. 2 is a flowchart illustrating a method of manufacturing a γ-GeSe layer, according to another embodiment;

FIG. 3 is a diagram illustrating a method of manufacturing a gamma-germanium selenide (GeSe) layer, according to an embodiment;

FIGS. 4 to 6 are optical microscope images illustrating a method of manufacturing a gamma-germanium selenide (γ-GeSe) layer, according to an embodiment;

FIGS. 7A to 7C are Raman spectroscopy graphs for illustrating a method of manufacturing a γ-GeSe layer, according to an embodiment;

FIG. 8 is an X-ray diffraction graph for illustrating a method of illustrating a γ-GeSe layer, according to an embodiment;

FIG. 9 is a graph illustrating a method of manufacturing a γ-GeSe layer, according to an embodiment;

FIGS. 10, 11A, and 11B are optical microscope images illustrating a method of manufacturing a γ-GeSe layer, according to an embodiment;

FIG. 12 is an optical microscope image illustrating a method of manufacturing a γ-GeSe layer, according to an embodiment;

FIG. 13 is an equivalent circuit diagram of a memory device manufactured by a method of manufacturing a memory device, according to an embodiment;

FIG. 14 is a perspective view illustrating a memory device manufactured by a method of manufacturing a memory device, according to an embodiment;

FIG. 15 is a cross-sectional view taken along lines X-X′ and Y-Y′ of FIG. 14;

FIG. 16 is a perspective view illustrating a memory device manufactured by a method of manufacturing a memory device, according to an embodiment;

FIG. 17 is a cross-sectional view taken along lines 2X-2X′ and 2Y-2Y′ of FIG. 16;

FIG. 18 is a flowchart illustrating a method of manufacturing a memory device, according to an embodiment;

FIGS. 19 to 21 are cross-sectional views showing a method of manufacturing a memory device, according to an embodiment; and

FIG. 22 is a block diagram of a memory system including a memory device manufactured by a method of manufacturing a memory device, according to an embodiment.

### DETAILED DESCRIPTION OF THE EMBODIMENTS

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, embodiments of inventive concepts will be described in detail with reference to the attached drawings.

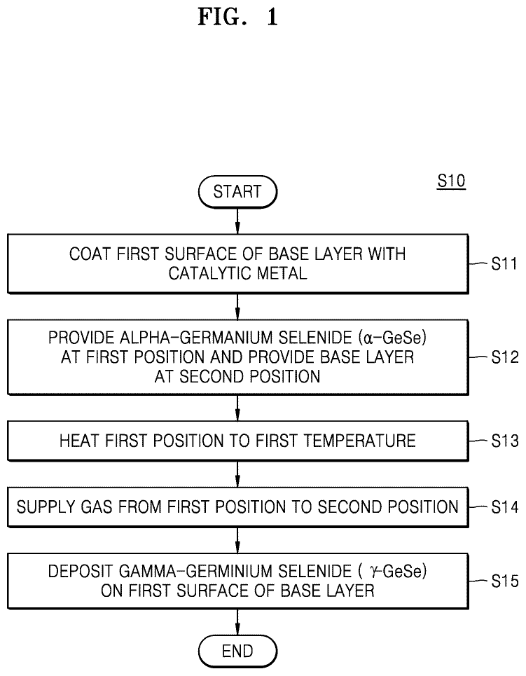

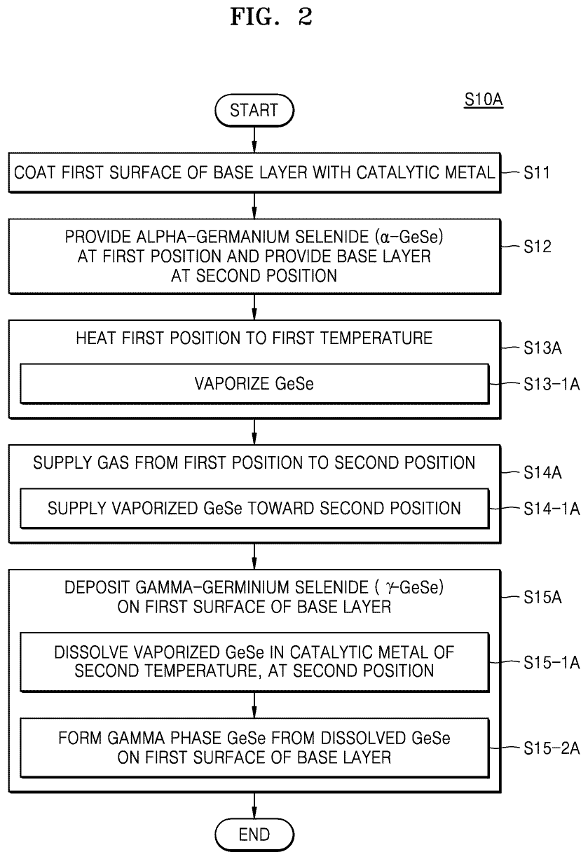

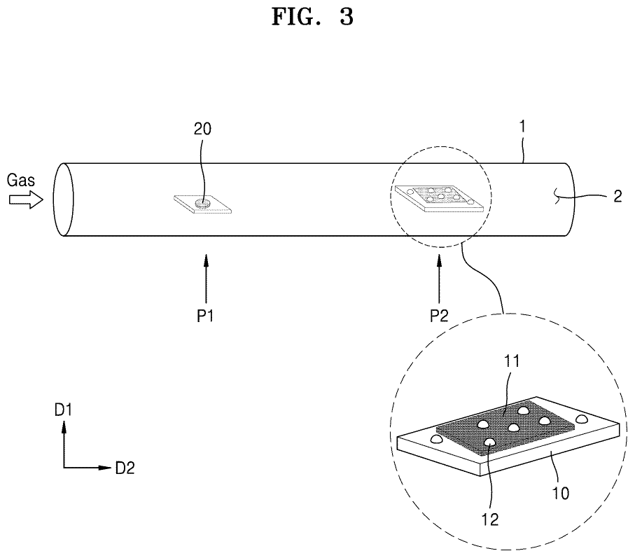

FIG. 1 is a flowchart illustrating a method of manufacturing a gamma-germanium selenide (GeSe) layer (S10) according to an embodiment. FIG. 2 is a flowchart illustrating a method of manufacturing a gamma-germanium selenide (GeSe) layer (S10A) according to an embodiment. FIG. 3 is a diagram illustrating a method of manufacturing a gamma-germanium selenide (GeSe) layer (S10 and S10A) according to an embodiment.

Referring to FIG. 1, an operation S11 of coating a first surface of a base layer with a catalytic metal may be performed.

Specifically, referring to FIG. 3 together, the base layer 11 may be arranged on a substrate 10. The base layer 11 may include a crystalline material.

In embodiments, the substrate 10 may include silicon dioxide (SiO₂).

In embodiments, the crystalline material of the base layer 11 may include a material in which a crystal system is hexagonal. In embodiments, the crystalline material of the base layer 11 may include a material having the same crystal system as a gamma-germanium selenide (γ-GeSe) layer formed through a subsequent process. In the present specification, γ-GeSe may refer to a gamma-phase GeSe. For example, the crystalline material of the base layer 11 may include hexagonal-boron nitride or graphene.

In embodiments, the crystalline material of the base layer 11 may include a material that does not react with γ-GeSe formed through a subsequent process.

In embodiments, the base layer 11 may include hexagonal-boron nitride, single crystal graphene, or polycrystalline graphene.

In embodiments, a first surface of the base layer 11 may be coated with a catalytic metal 12. The first surface of the base layer 11 may be a surface facing upward in a first horizontal direction (X direction). For example, the catalytic metal 12 may include gold (Au). In embodiments, the catalytic metal 12 may be coated on the first surface of the base layer 11 by a physical deposition method.

Referring back to FIG. 1, an operation S12 of providing alpha-germanium selenide (α-GeSe) to a first position and providing a base layer to a second position may be performed.

Specifically, referring to FIG. 3 together, a cylindrical quartz tube 1 may include a processing space 2 therein, and an α-GeSe 20 may be provided at the first position P1 in the processing space 2. At room temperature, the α-GeSe 20 may be in a powder state. In the present specification, α-GeSe may refer to an alpha phase GeSe.

In embodiments, the base layer 11 may be provided at a second position P2 in the processing space 2. The second position P2 may be spaced apart from the first position P1 in a second direction D2 crossing the first horizontal direction (X direction). The base layer 11 may be arranged on the substrate 10 and may be provided at the second position P2 in a state in which the catalytic metal 12 is coated on the first surface of the base layer 11.

Referring back to FIG. 1, an operation S13 of heating the first position to a first temperature may be performed.

Referring to FIG. 3 together, the first position P1 in the processing space 2 may be heated to the first temperature. Specifically, a heating device (not shown) (e.g., electrical circuit heater) covering the first position P1 may heat the processing space 2 at the first position P1. The heating device may not cover the second position P2. For example, the first temperature may be about 400° C. to about 600° C. For example, the first temperature may be about 550° C.

In embodiments, while the first position P1 in the processing space 2 is heated to the first temperature, the second position P2 may be heated to the second temperature. The second temperature may be lower than the first temperature. For example, the second temperature may be less than about 400° C. For example, the second temperature may be about 300° C. to about 400° C. For example, the second temperature may be about 350° C. to about 400° C. For example, the second temperature may be about 370° C.

In this case, referring to FIG. 2 as well, an operation S13A of heating the first position to the first temperature may include an operation S13-1A of vaporizing the GeSe by heating the first position to the first temperature.

Specifically, when the α-GeSe 20 in a powder state is heated to the first temperature, the α-GeSe 20 may vaporize. Specifically, at least a part of the α-GeSe 20 may vaporize even at a temperature below the temperature at which the α-GeSe 20 phase-changes into a gas phase. For example, the bond between germanium (Ge) and selenide (Se) of some α-GeSe 20 is broken at the first temperature, allowing the germanium (Ge) element and selenide (Se) element to vaporize, respectively.

Referring back to FIG. 1, an operation S14 of supplying gas from the first position to the second position may be performed.

Referring to FIG. 3 together, gas may be supplied in a direction from the first position P1 to the second position P2, that is, in a second direction D2 in the processing space 2. The gas may be supplied to the second position P2 through the first position P1.

In embodiments, the gas may include an inert gas or a nitrogen (N) gas. For example, the gas may include argon (Ar) gas.

In this case, referring to FIG. 2 together, an operation S14A of supplying gas from the first position to the second position may include an operation S14-1A of supplying gas from the first position to the second position and supplying the vaporized GeSe toward the second position.

For example, the gas may be for supplying the vaporized GeSe at the first position P1 to the second position P2. For example, the gas may not participate in a reaction process. For example, the gas may not participate in the processes of the vaporization of α-GeSe 20 and the formation of γ-GeSe through subsequent processes from the vaporized GeSe. For example, the gas may not react with alpha-germanium selenide α-GeSe 20, vaporized GeSe, and γ-GeSe formed through subsequent processes.

Referring back to FIG. 1, an operation S15 of depositing γ-GeSe on the first surface of the base layer may be performed.

Specifically, referring to FIG. 2 together, the operation S15A of depositing γ-GeSe on the first surface of the base layer may include an operation S15-1A of dissolving the vaporized-state GeSe in a catalytic metal of the second temperature at the second position, and an operation S15-2A of forming gamma-phase GeSe (γ-GeSe) on the first surface of the base layer by using the dissolved GeSe.

In embodiments, the vaporized-state GeSe supplied to the second position P2 through operation S14-1A may be dissolved in the catalytic metal 12 on the first surface of the base layer 11. For example, the vaporized-state GeSe may be dissolved in the catalytic metal 12 on the first surface of the base layer 11 and liquidated.

In embodiments, the dissolved GeSe may form γ-GeSe on the first surface of the base layer 11 having the second temperature. For example, the vaporized GeSE at the first temperature may be deposited on the first surface of the base layer 11 at the second temperature lower than the first temperature to form γ-GeSe. In embodiments, the γ-GeSe deposited on the first surface of the base layer 11 may be epitaxially grown on the first surface of the base layer 11. For example, the crystalline material of the base layer 11 may form a superlattice with γ-GeSe, so that γ-GeSe grows epitaxially.

The γ-GeSe layer may be manufactured by the method of manufacturing the γ-GeSe layer (S10 and S10A) described with reference to FIGS. 1 to 3.

In embodiments, the crystal system of the γ-GeSe layer may be a hexagonal system. In embodiments of inventive concepts, the yield and purity of the manufacturing process of the γ-GeSe layer may be improved by using, as the base layer, a crystalline material having the same crystal system as the crystal system of the γ-GeSe layer to be manufactured.

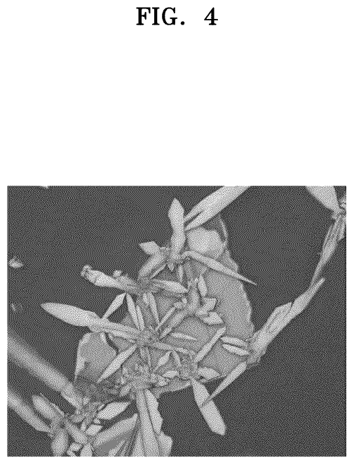

Hereinafter, the method (S10 and S10A) of manufacturing a γ-GeSe layer described with reference to FIGS. 1 to 3 will be described in detail with reference to FIGS. 4 to 9.

FIGS. 4 to 6 are optical microscope images illustrating a method of manufacturing a gamma-germanium selenide (γ-GeSe) layer according to an embodiment.

FIG. 4 is an image showing a result of depositing a γ-GeSe layer using hexagonal-boron nitride as a crystalline material for the base layer.

Referring to FIG. 4, it may be confirmed that a γ-GeSe layer is deposited on hexagonal-boron nitride. For example, when a base layer of hexagonal-boron nitride is provided on a silicon dioxide (SiO₂) substrate and the γ-GeSe layer manufacturing method (S10 and S10A) described with reference to FIGS. 1 to 3 is performed, it may be confirmed that the γ-GeSe layer is deposited on the hexagonal-boron nitride base layer.

In this case, the directions of γ-GeSe crystals grown on the same hexagonal-boron nitride base layer may be well aligned. In addition, impurities, e.g., α-GeSe, may not be formed on the hexagonal-boron nitride base layer.

In embodiments, the crystal system of hexagonal-boron nitride is the same hexagonal system as the crystal system of γ-GeSe. In addition, an in-plane lattice parameter of γ-GeSe is 3.73 Å, while an in-plane lattice parameter of hexagonal-boron nitride is 2.50 Å. The ratio of lattice parameters of the two materials is about 3:2, and γ-GeSe and hexagonal-boron nitride may form a superlattice. For example, four unit cells of γ-GeSe and nine unit cells of hexagonal-boron nitride may stably form a superlattice. In addition, hexagonal-boron nitride has chemical and structural stability at high temperatures (for example, the second temperature of about 300° C. to about 400° C.). Due to the above features, hexagonal-boron nitride may provide a good environment for the growth of γ-GeSe. In addition, α-GeSe and γ-GeSe may grow competitively on the base layer. As hexagonal-boron nitride provides a favorable environment for γ-GeSe to grow, growth of α-GeSe, which is an impurity, may decrease.

According to embodiments, the yield and purity of γ-GeSe may be improved by a method of manufacturing γ-GeSe using hexagonal-boron nitride as the base layer.

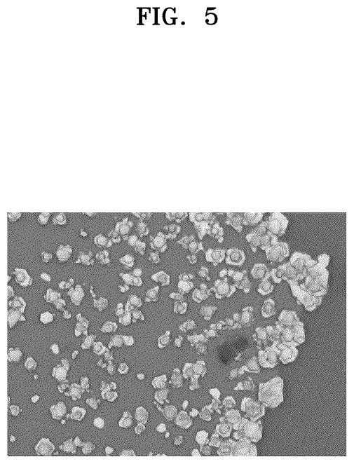

FIG. 5 is an image showing a result of depositing a γ-GeSe layer by using single crystal graphene as a crystalline material of a base layer.

Referring to FIG. 5, it may be confirmed that a γ-GeSe layer has been deposited on single crystal graphene. For example, when a base layer of single crystal graphene is provided on a silicon dioxide substrate and the γ-GeSe layer manufacturing method (S10 and S10A) described with reference to FIGS. 1 to 3 is performed, it may be confirmed that a γ-GeSe layer is deposited on the single crystal graphene base layer. In this case, impurities, e.g., α-GeSe, may not be formed on the single crystal graphene base layer. In addition, it may be seen that γ-GeSe was not formed on some parts (the lower right part and the upper right part in FIG. 5) of the substrate that did not provide single crystal graphene. Accordingly, it may be confirmed that γ-GeSe has been selectively deposited on single crystal graphene.

In embodiments, the crystal system of single crystal graphene is the same hexagonal system as the crystal system of γ-GeSe. In addition, the in-plane lattice parameter of γ-GeSe is 3.73 Å, while that of graphene is 2.46 Å. The ratio of lattice parameters of the two materials is about 3:2, and γ-GeSe and single crystal graphene may form a superlattice. For example, four unit cells of γ-GeSe and nine unit cells of single crystal graphene may stably form a superlattice. In addition, graphene has chemical and structural stability at high temperatures (for example, the second temperature of about 300° C. to about 400° C.). Due to the above features, single crystal graphene may provide a good environment for the growth of γ-GeSe. In addition, α-GeSe and γ-GeSe may grow competitively on the base layer. As single crystal graphene provides a favorable environment for γ-GeSe to grow, growth of α-GeSe, which is an impurity, may decrease.

That is, according to embodiments, the yield and purity of γ-GeSe may be improved by a method of manufacturing γ-GeSe using single crystal graphene as the base layer.

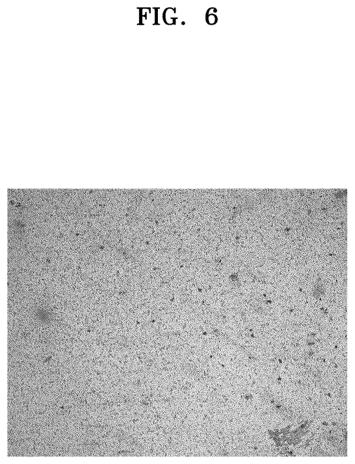

FIG. 6 is an image showing a result of depositing a γ-GeSe layer by using polycrystalline graphene as a crystalline material of a base layer.

Referring to FIG. 6, it may be confirmed that a γ-GeSe layer has been deposited on polycrystalline graphene. For example, a base layer of polycrystalline graphene may be provided on a silicon dioxide substrate by chemical vapor deposition (CVD). In this case, the polycrystalline graphene may form a plate covering the substrate.

In embodiments, when the γ-GeSe layer manufacturing method (S10 and S10A) described with reference to FIGS. 1 to 3 was performed, it was confirmed that the γ-GeSe layer was deposited on the polycrystalline graphene base layer. In this case, impurities, e.g., α-GeSe, may not be formed on the polycrystalline graphene base layer.

In embodiments, the crystal system of polycrystalline graphene is the same hexagonal system as the crystal system of γ-GeSe. In addition, like single crystal graphene, polycrystalline graphene may form a superlattice with γ-GeSe. For example, four unit cells of γ-GeSe and nine unit cells of polycrystalline graphene may stably form a superlattice. Like the single crystal graphene, polycrystalline graphene may provide a good environment for the growth of γ-GeSe. In addition, as described above, polycrystalline graphene may be formed on a substrate in a large area, and γ-GeSe may act as a base layer that may grow in a large area as well.

In addition, α-GeSe and γ-GeSe may grow competitively on the base layer. As polycrystalline graphene provides a favorable environment for γ-GeSe to grow, growth of α-GeSe, which is an impurity, may decrease.

That is, according to embodiments, the yield and purity of γ-GeSe may be improved by a method of manufacturing γ-GeSe using polycrystalline graphene as the base layer.

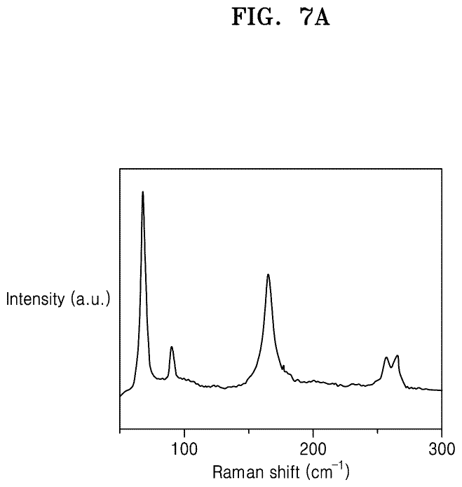

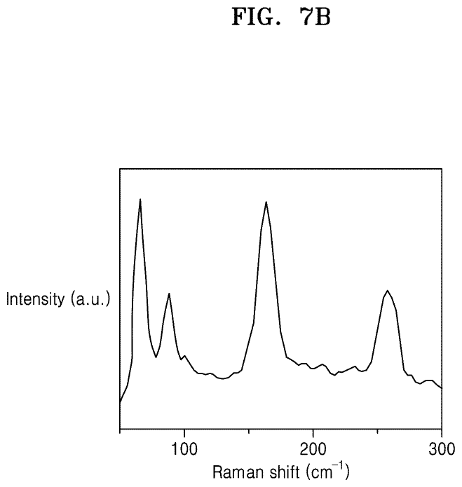

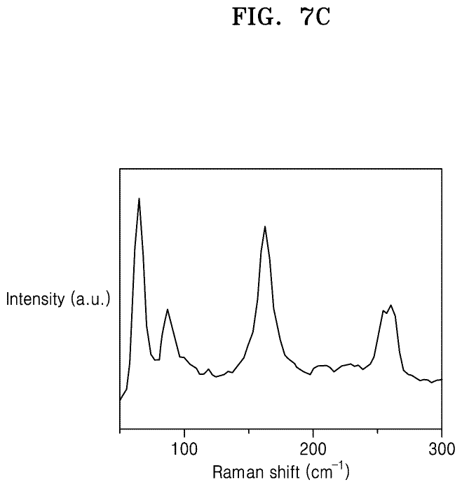

FIGS. 7A to 7C are Raman spectroscopy graphs for illustrating a method of manufacturing a γ-GeSe layer according to an embodiment. Specifically, FIGS. 7A to 7C are graphs showing Raman spectroscopy of γ-GeSe prepared by a γ-GeSe layer manufacturing method using single crystal graphene, polycrystalline graphene, and hexagonal-boron nitride as crystalline materials for the base layer, respectively.

Referring to FIGS. 7A, 7B, and 7C, it may be confirmed that γ-GeSe has been formed on the single crystal graphene, the polycrystalline graphene, and the hexagonal-boron nitride described with reference to FIGS. 4 to 6.

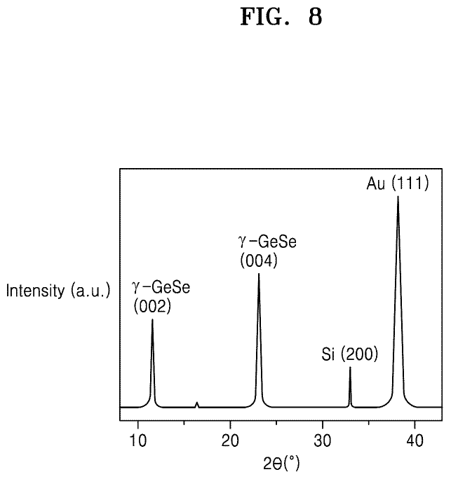

FIG. 8 is an X-ray diffraction graph for illustrating a method of illustrating a γ-GeSe layer according to an embodiment. Specifically, FIG. 8 is a graph showing X-ray diffraction of γ-GeSe prepared by a γ-GeSe layer manufacturing method using polycrystalline graphene as a crystalline material for a base layer.

Referring to FIG. 8, it may be found that materials other than γ-GeSe, silicon (Si), and gold (Au) were not observed on the X-ray diffraction graph. Since silicon (Si) is a component of silicon dioxide used as a substrate and gold is a component of catalytic metal, it may be confirmed that materials other than γ-GeSe were not manufactured by the method of manufacturing a γ-GeSe layer according to an embodiment. In other words, it may be confirmed that α-GeSe, which is an impurity, was not synthesized.

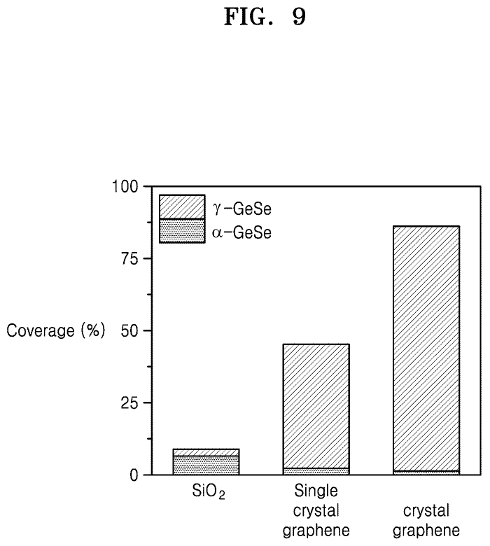

FIG. 9 is a graph illustrating a method of manufacturing a γ-GeSe layer according to an embodiment. Specifically, FIG. 9 shows area ratio (coverage) histograms of γ-GeSe and α-GeSe when a silicon dioxide substrate without providing a base layer, single crystal graphene is used as the base layer, and polycrystalline graphene is used as the base layer. In the present specification, the area ratio (coverage) may mean a ratio at which each material covers the base layer.

Referring to FIG. 9, it may be confirmed that α-GeSe has been mainly formed on a silicon dioxide substrate that does not provide a base layer. Although γ-GeSe is formed on a silicon dioxide substrate without a base layer, γ-GeSe is formed at a lower rate than α-GeSe, and the area ratio (coverage) is also lower than in the other two cases where graphene was used as the base layer.

Referring back to FIG. 9, when single crystal graphene is used as the base layer, it may be confirmed that γ-GeSe has been mainly formed. It may be seen that the area ratio of α-GeSe has been smaller than that of γ-GeSe, and the area ratio of γ-GeSe has been also increased compared to the case on a silicon dioxide substrate that did not provide a base layer.

Referring back to FIG. 9, when polycrystalline graphene is used as the base layer, it may be confirmed that γ-GeSe has been mainly formed. It may be seen that the area ratio of α-GeSe has been smaller than that of γ-GeSe, and the area ratio of γ-GeSe has been also increased compared to the case on a silicon dioxide substrate that did not provide a base layer, and the case when single crystal graphene was used as the base layer.

As described with reference to FIGS. 4 to 9, when γ-GeSe was prepared by the γ-GeSe manufacturing method described with reference to FIGS. 1 to 3 using hexagonal-boron nitride, single crystal graphene, and polycrystalline graphene as the base layer, γ-GeSe was formed on the base layer of hexagonal-boron nitride, single crystal graphene, and polycrystalline graphene, the purity and yield were enhanced, and the area ratio may be improved.

That is, according to inventive concepts, the method (S10 and S10A) of manufacturing a γ-GeSe layer with improved yield and purity and improved area ratio may be provided.

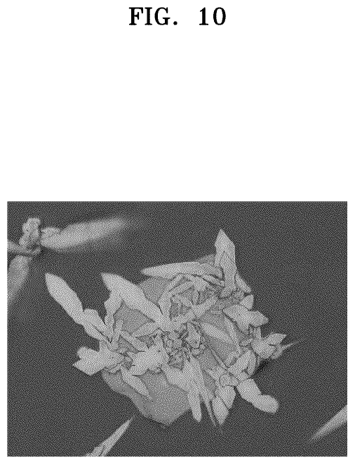

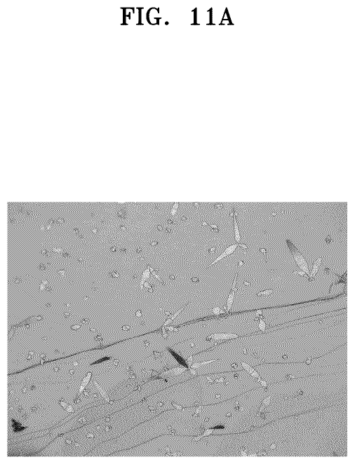

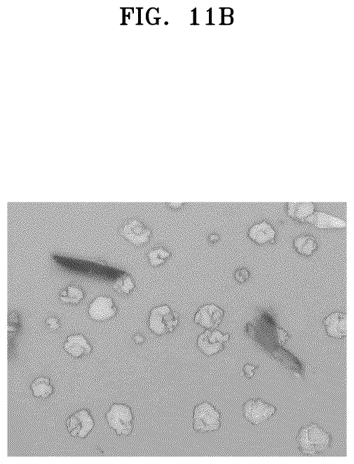

FIGS. 10, 11A, and 11B are optical microscope images illustrating a method of manufacturing a γ-GeSe layer according to an embodiment.

FIG. 10 is an image showing the result of depositing a γ-GeSe layer using a highly oriented pyrolytic graphite (HOPG) exfoliated with a tape as a crystalline material of a base layer.

Referring to FIG. 10, it may be confirmed that a γ-GeSe layer has been deposited on a HOPG. For example, when a base layer of a HOPG is provided on a silicon dioxide (SiO₂) substrate and the γ-GeSe layer manufacturing method (S10 and S10A) described with reference to FIGS. 1 to 3 is performed, it may be confirmed that the γ-GeSe layer is deposited on the HOPG base layer.

The HOPG is a stack of graphene and may have properties similar to graphene. That is, the HOPG may provide a good environment for the growth of γ-GeSe.

According to embodiments, the yield and purity of γ-GeSe may be improved by a method of manufacturing γ-GeSe using the HOPG as the base layer.

FIGS. 11A and 11B are images showing the results of depositing a γ-GeSe layer by using the whole HOPG as a base layer.

Referring to FIGS. 11A and 11B, it may be confirmed that a γ-GeSe layer has been deposited on a HOPG.

According to embodiments, the yield and purity of γ-GeSe may be improved by a method of manufacturing γ-GeSe using the HOPG as the base layer.

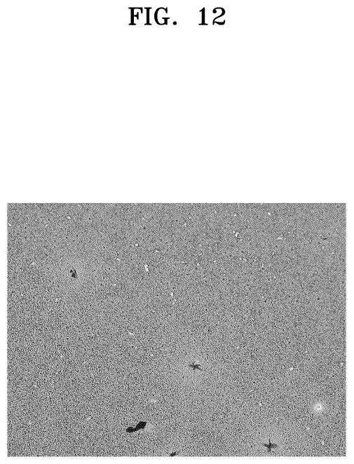

FIG. 12 is an optical microscope image illustrating a method of manufacturing a γ-GeSe layer according to an embodiment. Specifically, FIG. 12 is an image of a comparative example using gold (Au) as a base layer.

Referring to FIG. 12, in the case of Comparative Example in which gold (Au) was used as the base layer, it may be seen that γ-GeSe was not formed.

In embodiments, gold (Au) is a material provided as a catalytic metal on a base layer to form γ-GeSe. When gold (Au) is used as a base layer, gold (Au) becomes excessively involved in the deposition process of GeSe, and thus, γ-GeSe may not grow.

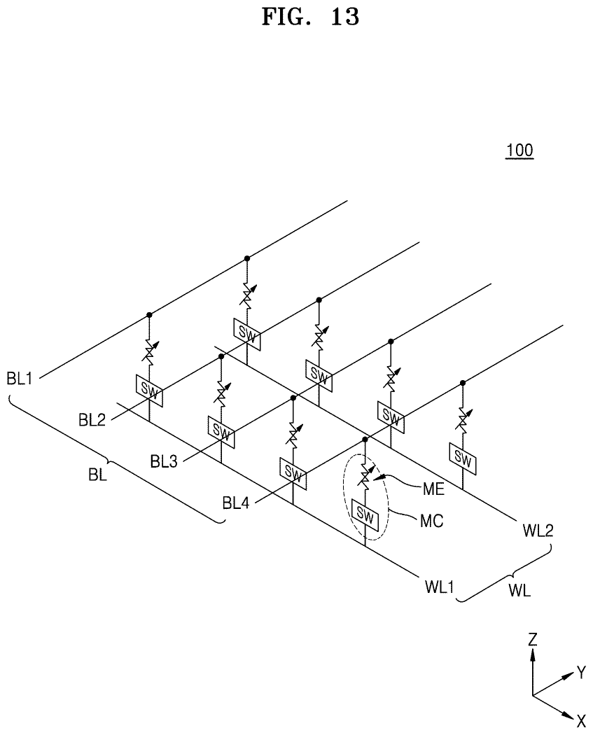

FIG. 13 is an equivalent circuit diagram of a memory device 100 manufactured by a method of manufacturing the memory device 100 according to an embodiment.

Referring to FIG. 13, the memory device 100 may include word lines WL1 and WL2 extending in a first horizontal direction (X direction) and spaced apart from each other in a second horizontal direction (Y direction) perpendicular to the first horizontal direction (X direction). In addition, the memory device 100 may include bit lines BL (e.g., BL1, BL2, BL3, and BL4) spaced apart from the word line WL in a vertical direction (Z direction) and extending in a second horizontal direction (Y direction).

Each of the memory cells MC may be arranged between the bit line BL and the word line WL. Specifically, the memory cell MC may be arranged at an intersection of the bit line BL and the word line WL, and may include a variable resistance layer ME for storing information and a selection element layer SW for selecting the memory cell MC. Meanwhile, the selection element layer SW may be referred to as a switching element layer or an access element layer.

The memory cells MC may be arranged in the same structure in the third direction (Z direction). For example, in the memory cell MC arranged between the word line WL1 and the bit line BL1, the selection element layer SW may be electrically connected to the word line WL1, the variable resistance layer ME may be electrically connected to the bit line BL1, and the variable resistance layer ME and the selection element layer SW may be connected in series.

However, embodiments are not limited thereto. For example, unlike the illustration, the positions of the selection element layer SW and the variable resistance layer ME may be changed in the memory cell MC. That is, in the memory cell MC, the variable resistance layer ME may be connected to the word line WL1, and the selection element layer SW may be connected to the bit line BL1.

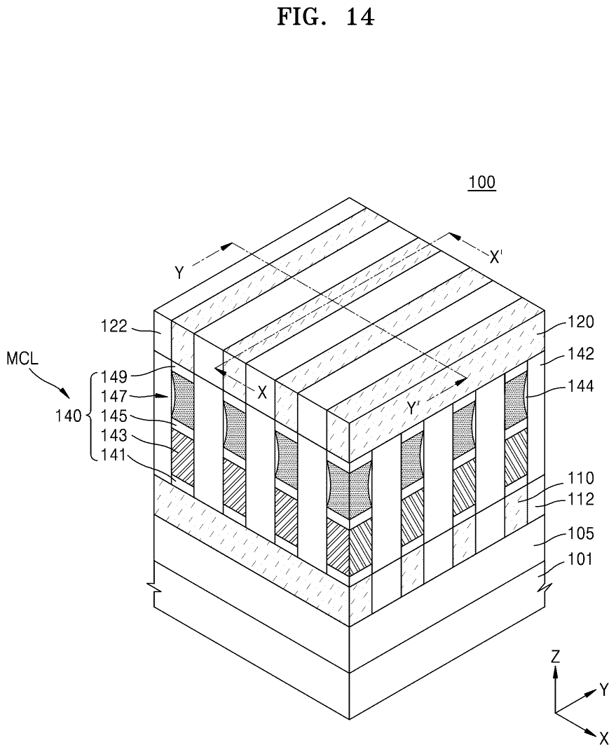

A driving method of the memory device 100 will be briefly described. A voltage is applied to the variable resistance layer ME of the memory cell MC through the word line WL and the bit line BL, and thus a current may flow through the variable resistance layer ME. For example, the variable resistance layer ME may include a phase change layer 147 (see FIG. 14), which may reversibly transition between a first state and a second state. However, the variable resistance layer ME is not limited thereto, and any variable resistor of which the resistance value varies depending on the applied voltage may be included. For example, in the selected memory cell MC, the resistance of the variable resistance layer ME may reversibly transition between the first state and the second state according to the voltage applied to the variable resistance layer ME.

According to a change in resistance of the variable resistance layer ME, the memory cell MC may store digital information such as “0” or “1”, and digital information may also be erased from the memory cell MC. For example, data may be written in a high resistance state “0” and a low resistance state “1” in the memory cell MC. Here, writing from the high resistance state “0” to the low resistance state “1” may be referred to as a “set operation”, and writing from the low resistance state “1” to the high resistance state “0” may be referred to as a “reset operation”.

However, the memory cell MC is not limited to digital information of the high resistance state “0” and the low resistance state “1”, and may store various resistance states in various forms (e.g., 0, 1, 2, 3, etc.).

In addition, any memory cell MC may be addressed by the selection of the word line WL and the bit line BL, and the memory cell MC may be programmed by applying a desired and/or alternatively predetermined signal between the word line WL and the bit line BL. In addition, by measuring the current value through the bit line BL, information according to the resistance value of the variable resistance layer ME of the memory cell MC, that is, programmed information, may be read.

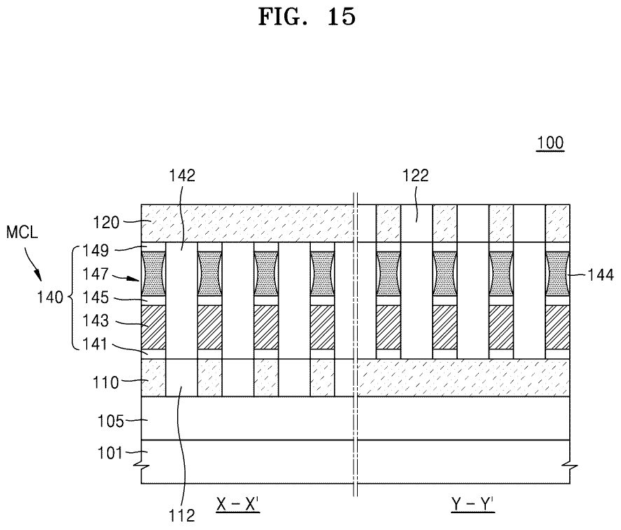

FIG. 14 is a perspective view illustrating a memory device 100 manufactured by a method of manufacturing a memory device 100 according to an embodiment. FIG. 15 is a cross-sectional view taken along lines X-X′ and Y-Y′ of FIG. 14.

Referring to FIGS. 14 and 15, the memory device 100 may include a first conductive line 110, a second conductive line 120, and a memory cell layer MCL on the substrate 101.

An interlayer insulating layer 105 may be arranged on the substrate 101. The interlayer insulating layer 105 may include silicon oxide or silicon nitride, and may serve to electrically separate the first conductive line 110 from the substrate 101. In the memory device 100 of the present embodiment, the interlayer insulating layer 105 is arranged on the substrate 101, but this is only an example. For example, in the memory device 100 of this embodiment, an integrated circuit layer may be arranged on the substrate 101, and memory cells may be arranged on the integrated circuit layer. The integrated circuit layer may include, for example, a peripheral circuit for operations of memory cells and/or a core circuit for operations and/or the like. For reference, a structure in which an integrated circuit layer including a peripheral circuit and/or a core circuit is arranged on the substrate 101 and memory cells are arranged on the integrated circuit layer is referred to as a Cell On Pei (COP) structure.

A plurality of first conductive lines 110 may extend in parallel to each other in the first horizontal direction (X direction). A plurality of second conductive lines 120 may extend in parallel to each other in a second horizontal direction (Y direction) that intersects the first horizontal direction (X direction). The first horizontal direction (X direction) and the second horizontal direction (Y direction) may be orthogonal to each other.

In terms of driving the memory device 100, the first conductive lines 110 may correspond to the word line WL (refer to FIG. 13), and the second conductive lines 120 may correspond to the bit line BL (refer to FIG. 13). In addition, on the contrary, the first conductive lines 110 may correspond to the bit line BL (refer to FIG. 9), and the second conductive lines 120 may correspond to the word line WL (refer to FIG. 9).

Each of the first conductive lines 110 and the second conductive lines 120 may include a metal, a conductive metal nitride, a conductive metal oxide, or a combination thereof. For example, each of the first conductive lines 110 and the second conductive lines 120 may include W, WN, Au, Ag, Cu, Al, TiAlN, Ir, Pt, Pd, Ru, Zr, Rh, Ni, Co, Cr, Sn, Zn, ITO, or a combination thereof. In addition, each of the first conductive lines 110 and the second conductive lines 120 may include a metal layer and a conductive barrier layer covering at least a portion of the metal layer. The conductive barrier layer may include, for example, Ti, TiN, Ta, TaN, or a combination thereof.

The memory cell layer MCL may include a plurality of memory cells 140 spaced apart from each other in a first horizontal direction (X direction) and a second horizontal direction (Y direction). As illustrated, the first conductive lines 110 and the second conductive lines 120 may cross each other. The memory cells 140 may be respectively arranged at portions where each of the first conductive lines 110 and the second conductive lines 120 perpendicularly overlap between the first conductive lines 110 and the second conductive lines 120.

Each of the memory cells 140 may be formed in a pillar structure having a rectangular pillar. Of course, the structure of each of the memory cells 140 is not limited to a rectangular pillar. For example, the memory cells 140 may have various pillar shapes such as a circular column, an elliptical column, and a polygonal column. In addition, depending on the formation method, the memory cells 140 may have a structure in which the lower part is wider than the upper part or a structure in which the upper part is wider than the lower part. For example, when the memory cells 140 are formed through an embossed etching process, the lower part may have a structure wider than the upper part. In addition, when the memory cells 140 are formed through a damascene process, the upper part may have a wider structure than the lower part. Of course, in the embossed etching process or the damascene process, material layers may be etched so that the sidewalls are almost vertical by precisely controlling the etching, so that there is little difference in width between the upper part and the lower part. In all of the drawings below, including FIGS. 14 and 15, the sidewalls of the memory cells 140 are shown vertically, but this is for convenience of illustration, and the memory cells 140 may have a structure where the lower part is wider than the upper part, or the upper part is wider than the lower part.

Each of the memory cells 140 may include a lower electrode 141, a switch layer 143, an intermediate electrode 145, a phase change layer 147, and an upper electrode 149. The switch layer 143 may correspond to the selection element layer SW described with reference to FIG. 13. The phase change layer 147 may correspond to the variable resistance layer ME described with reference to FIG. 13. When the positional relationship is not considered, the lower electrode 141 may be referred to as a first electrode, the intermediate electrode 145 may be referred to as a second electrode, and the upper electrode 149 may be referred to as a third electrode.

The phase change layer 147 may electrically connect the intermediate electrode 145 with the upper electrode 149. The phase change layer 147 may be a phase change pattern. The phase change layer 147 may store data by changing resistance according to a change in temperature.

In embodiments, the phase change layer 147 may include a portion in which the width in the first horizontal direction (X direction) gradually increases from the second conductive line 120 to the first conductive line 110. In addition, the phase change layer 147 may include a portion in which the width in the first horizontal direction (X direction) gradually decreases from the second conductive line 120 to the first conductive line 110. In addition, the phase change layer 147 may include a portion in which the width in the first horizontal direction (X direction) gradually decreases and then increases from the second conductive line 120 to the first conductive line 110.

Likewise, the phase change layer 147 may include a portion in which the width in the second horizontal direction (Y direction) gradually increases from the first conductive line 110 to the second conductive line 120. In addition, the phase change layer 147 may include a portion in which the width in the second horizontal direction (Y direction) gradually decreases from the first conductive line 110 to the second conductive line 120. In addition, the phase change layer 147 may include a portion in which the width in the second horizontal direction (Y direction) gradually decreases and then increases from the first conductive line 110 to the second conductive line 120.

That is, the phase change layer 147 may have an hourglass shape. However, embodiments are not limited thereto, and the width of the phase change layer 147 in the first horizontal direction (X direction) and the width in the second horizontal direction (Y direction) may be constant.

The phase change layer 147 may include, for example, a compound in which at least one of S, Te, and Se, which are chalcogen elements, and at least one of Ge, Sb, Bi, Sn, Ag, As, Si, In, Ga, Ce, Y, Al, Tl, Nd, Dy, Sc, and Zn are combined.

For example, the phase change layer 147 may include at least one of GeTe, GeSe, GeS, SbSe, SbTe, SbS, SbSe, SnSb, InSe, InSb, AsTe, AlTe, GaSb, AlSb, BiSb, ScSb, YSb, CeSb, DySb, NdSb, GeSbSe, AlSbTe, AlSbSe, SiSbSe, SiSbTe, GeSeTe, InGeTe, GeSbTe, GeAsTe, SnSeTe, GeGaSe, BiSbSe, GaSeTe, InGeSb, GaSbSe, GaSbTe, InSbSe, InSbTe, SnSbSe, SnSbTem ScSbTe, ScSbSe, ScSbS, YSbTe, YSbSe, YSbS, CeSbTe, CeSbSe, CeSbS, DySbTe, DySbSe, DySbS, NdSbTe, NdSbSe, NdSbS, GeSbTeS, BiSbTeSe, AgInSbTe, GeSbSeTe, GeSnSbTe, SiGeSbTe, SiGeSbSe, SiGeSeTe, BiGeSeTe, BiSiGeSe, BiSiGeTe, GeSbTeBi, GeSbSeBi, GeSbSeIn, GeSbSeGa, GeSbSeAl, GeSbSeTl, GeSbSeSn, GeSbSeZn, GeSbTeIn, GeSbTeGa, GeSbTeAl, GeSbTeTl, GeSbTeSn, GeSbTeZn, ScGeSbTe, ScGeSbSe, ScGeSbS, YGeSbTe, YGeSbSe, YGeSbS, CeGeSbTe, CeGeSbSe, CeGeSbS, DyGeSbTe, DyGeSbSe, DyGeSbS, NdGeSbTe, NdGeSbSe, NdGeSbS, InSbTeAsSe, GeScSbSeTe, GeSbSeTeS, GeScSbSeS, GeScSbTeS, GeScSeTeS, GeScSbSeP, GeScSbTeP, GeSbSeTeP, GeScSbSeIn, GeScSbSeGa, GeScSbSeAl, GeScSbSeTl, GeScSbSeZn, GeScSbSeSn, GeScSbTeIn, GeScSbTeGa, GeSbAsTeAl, GeScSbTeTl, GeScSbTeZn, GeScSbTeSn, GeSbSeTeIn, GeSbSeTeGa, GeSbSeTeAl, GeSbSeTeTl, GeSbSeTeZn, GeSbSeTeSn, GeSbSeSIn, GeSbSeSGa, GeSbSeSAl, GeSbSeSTl, GeSbSeSZn, GeSbSeSSn, GeSbTeSIn, GeSbTeSGa, GeSbTeSAl, GeSbTeSTl, GeSbTeSZn, GeSbTeSSn, GeSbSeInGa, GeSbSeInAl, GeSbSeInTl, GeSbSeInZn, GeSbSeInSn, GeSbSeGaAl, GeSbSeGaTl, GeSbSeGaZn, GeSbSeGaSn, GeSbSeAlTl, GeSbSeAlZn, GeSbSeAlSn, GeSbSeTIZn, GeSbSeTISn, and GeSbSeZnSn. In embodiments, the phase change layer 147 may include GeSbTe (GST).

For example, the phase change layer 147 may include a γ-GeSe layer produced by the γ-GeSe layer manufacturing method (S10 and S10A) according to an embodiment described with reference to FIGS. 1 to 3. Although not shown in FIGS. 14-15, the base layer 11 described in FIG. 3 may be formed between the intermediate electrode 145 and the phase change layer 147 and the phase change 147 may include a γ-GeSe layer produced by the γ-GeSe layer manufacturing method (S10 and S10A) according to an embodiment described with reference to FIGS. 1 to 3.

In embodiments, a spacer 144 may be arranged on a sidewall of the phase change layer 147. The spacer 144 may overlap the phase change layer 147 in the first horizontal direction (X direction). The spacer 144 may overlap the phase change layer 147 in the second horizontal direction (Y direction).

Although the spacer 144 is illustrated as a single layer, embodiments are not limited thereto, and the spacer 144 may include a double layer. The spacer 144 may include, for example, one of silicon oxide, silicon nitride, silicon oxynitride, and a combination thereof, but is not limited thereto.

The switch layer 143 may be a current adjustment layer capable of controlling a flow of current. The switch layer 143 may include a material layer whose resistance may change according to the magnitude of a voltage applied cross both ends of the switch layer 143.

The switch layer 143 may include an ovonic threshold switching (OTS) material. To briefly describe the function of the switch layer 143 based on the OTS material, when a voltage lower than a threshold voltage Vt is applied to the switch layer 143, the switch layer 143 maintains a high resistance state and through which little current flows. In addition, when a voltage greater than the threshold voltage Vt is applied to the switch layer 143, the switch layer 143 becomes a low resistance state and through which current begins to flow. In addition, when the current flowing through the switch layer 143 becomes less than a holding current, the switch layer 143 may change to a high resistance state.

The switch layer 143 may include, for example, a chalcogenide material. The chalcogenide material may include a compound in which at least one of S, Te, and Se, which are chalcogen elements, is combined with at least one of Ge, Sb, Bi, Al, Tl, Sn, Zn, As, Si, In, Ti, Ga, and P.

For example, the switch layer 143 may include at least one of GeSe, GeS, AsSe, AsTe, AsS, SiTe, SiSe, SiS, GeAs, SiAs, SnSe, SnTe, GeAsTe, GeAsSe, AlAsTe, AlAsSe, SiAsSe, SiAsTe, GeSeTe, GeSeSb, GaAsSe, GaAsTe, InAsSe, InAsTe, SnAsSe, SnAsTe, GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeln, GeAsSeGa, GeAsSeAl, GeAsSeTl, GeAsSeSn, GeAsSeZn, GeAsTeln, GeAsTeGa, GeAsTeAl, GeAsTeTl, GeAsTeSn, GeAsTeZn, GeSiAsSeTe, GeAsSeTeS, GeSiAsSeS, GeSiAsTeS, GeSiSeTeS, GeSiAsSeP, GeSiAsTeP, GeAsSeTeP, GeSiAsSeln, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSelnAl, GeAsSelnTl, GeAsSeInZn, GeAsSelnSn, GeAsSeGaAl, GeAsSeGaTl, GeAsSeGaZn, GeAsSeGaSn, GeAsSeAlTl, GeAsSeAlZn, GeAsSEAISn, GeAsSeTIZn, GeAsSeTISn, GeAsSeZnSn, GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSelnGa, GeSiAsSelnAl, GeSiAsSeInTl, GeSiAsSelnZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and GeAsSeSAISn.

The lower electrode 141, the intermediate electrode 145, and the upper electrode 149 may include a conductive material as a layer functioning as a current passage. For example, the lower electrode 141, the intermediate electrode 145, and the upper electrode 149 may each include a metal, a conductive metal nitride, a conductive metal oxide, or a combination thereof. For example, each of the lower electrode 141, the intermediate electrode 145, and the upper electrode 149 may include at least one selected from titanium nitride (TiN), titanium silicon nitride (TiSiN), titanium carbon nitride (TiCN), titanium carbon silicon nitride (TiCSiN), titanium aluminum nitride (TiAlN), tantalum (Ta), tantalum nitride (TaN), tungsten (W), and tungsten nitride (WN), but is not limited thereto.

The lower electrode 141 and the upper electrode 149 may be selectively formed. In other words, the lower electrode 141 and the upper electrode 149 may be omitted. However, in order to prevent contamination or contact failure that may occur when the switch layer 143 and the phase change layer 147 directly contact the first and second conductive lines 110 and 120, the lower electrode 141 and the upper electrode 149 may be respectively arranged between the first conductive line 110 and the switch layer 143 and between the second conductive line 120 and the phase change layer 147.

A first insulating layer 112 may be arranged between the first conductive lines 110 and a second insulating layer 142 may be arranged between the memory cells 140 of the memory cell layer MCL. In addition, a third insulating layer 122 may be arranged between the second conductive lines 120. The first to third insulating layers 112, 142, and 122 may include an insulating layer of the same material, or at least one of the first to third insulating layers 112, 142, and 122 may include an insulating layer of a different material. The first to third insulating layers 112, 142, and 122 may include, for example, a dielectric material of silicon oxide or silicon nitride, and may function to electrically separate devices of each layer from each other. Meanwhile, an air gap (not shown) may be formed in place of the second insulating layer 142. When the air gap is formed, an insulating liner (not shown) having a desired and/or alternatively predetermined thickness may also be formed between the air gap and the memory cell 140.

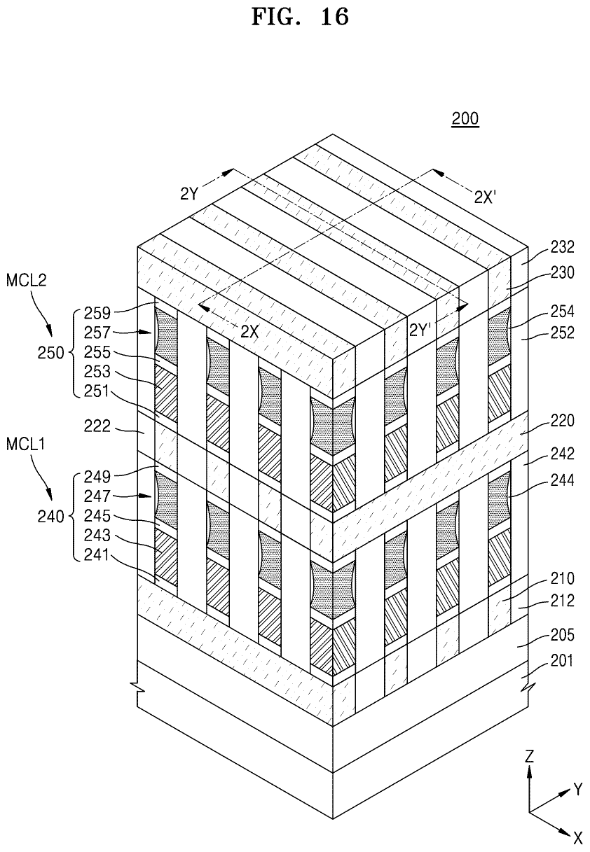

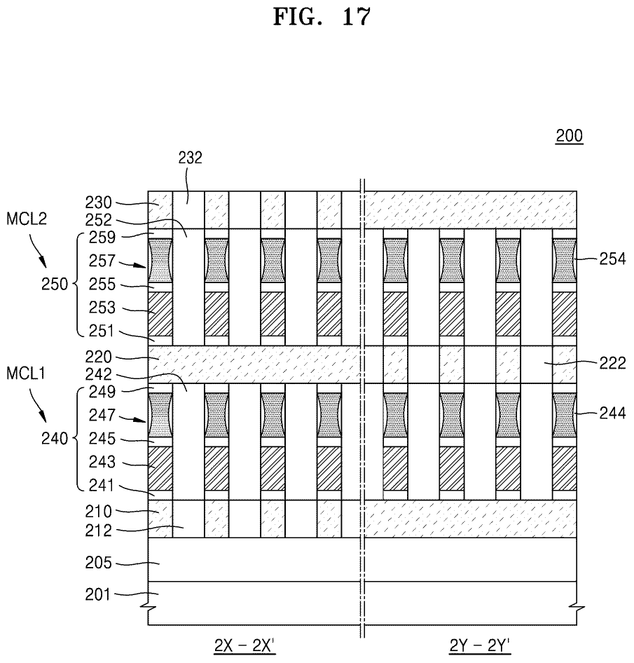

FIG. 16 is a perspective view illustrating a memory device 200 manufactured by a method of manufacturing a memory device 200 according to an embodiment. FIG. 17 is a cross-sectional view taken along lines 2X-2X′ and 2Y-2Y′ of FIG. 16.

Most components constituting the memory device 200 described below and materials constituting the components are substantially the same as or similar to those described above with reference to FIGS. 13 to 15. Therefore, for convenience of description, differences between a memory device 200 and the memory device 100 described above will be mainly described.

Referring to FIGS. 16 and 17, the memory device 200 may include a first conductive line 210, a second conductive line 220, a third conductive line 230, a first memory cell layer MCL1, and a second memory cell layer MCL2 on a substrate 201.

As illustrated, an interlayer insulating layer 205 may be arranged on the substrate 201. A plurality of first conductive lines 210 may extend in parallel to each other in the first horizontal direction (X direction). A plurality of second conductive lines 120 may extend in parallel to each other in a second horizontal direction (Y direction) perpendicular to the first horizontal direction (X direction). In addition, a plurality of third conductive lines 230 may extend in parallel to each other in the first horizontal direction (X direction). Meanwhile, the third conductive lines 230 may be substantially the same as the first conductive lines 210 in the extension direction or arrangement structure, differing only in the positions in the vertical direction (Z direction).

In terms of driving the memory device 200, the first conductive lines 210 and the third conductive lines 230 may correspond to the word line WL (refer to FIG. 13), and the second conductive lines 220 may correspond to the bit line BL (refer to FIG. 13). In addition, on the contrary, the first conductive lines 210 and the third conductive lines 230 may correspond to the bit line BL (see FIG. 13), and the second conductive lines 220 may correspond to the word line WL (see FIG. 13). When the first conductive lines 210 and the third conductive lines 230 correspond to the word line WL (see FIG. 13), the first conductive lines 210 corresponds to a lower word line, the third conductive lines 230 corresponds to an upper word line, and the second conductive lines 220 may correspond to a common bit line because the second conductive lines 220 are shared with the lower word line and the upper word line.

Each of the first conductive line 210, the second conductive line 220, and the third conductive line 230 may include a metal, a conductive metal nitride, a conductive metal oxide, or a combination thereof. In addition, the first conductive line 210, the second conductive line 220, and the third conductive line 230 may each include a metal layer and a conductive barrier layer covering at least a portion of the metal layer.

The first memory cell layer MCL1 may include a plurality of first memory cells 240 spaced apart from each other in the first horizontal direction (X direction) and the second horizontal direction (Y direction). The second memory cell layer MCL2 may include a plurality of second memory cells 250 spaced apart from each other in the first horizontal direction (X direction) and the second horizontal direction (Y direction). As illustrated, the first conductive line 210 and the second conductive line 220 may cross each other, and the second conductive line 220 and the third conductive line 230 may cross each other. The first memory cells 240 may be arranged at portions where the first conductive lines 210 and the second conductive lines 220 cross each other between the first conductive lines 210 and the second conductive lines 220. The second memory cells 250 may be arranged at portions where the second conductive lines 220 and the third conductive lines 230 cross each other between the second conductive lines 220 and the third conductive lines 230.

The first memory cell 240 and the second memory cell 250 may include lower electrodes 241 and 251, switch layers 243 and 253, intermediate electrodes 245 and 255, phase change layers 247 and 257, and upper electrodes 249 and 259, respectively. The structures of the first memory cell 240 and the second memory cell 250 may be substantially the same.

A first insulating layer 212 may be arranged between the first conductive lines 210, and a second insulating layer 242 may be arranged between the first memory cells 240 of the first memory cell layer MCL1. In addition, a third insulating layer 222 may be placed between the second conductive lines 220, a fourth insulating layer 252 may be placed between the second memory cells 250 of the second memory cell layer MCL2, and a fifth insulating layer 232 may be placed between the third conductive lines 230. The first to fifth insulating layers 212, 242, 222, 252, and 232 may include an insulating layer of the same material, or at least one of the first to fifth insulating layers 212, 242, 222, 252, and 232 may include an insulating layer of a different material. The first to fifth insulating layers 212, 242, 222, 252, and 232 may include, for example, an oxide or nitride dielectric material, and may function to electrically separate devices of each layer from each other. Meanwhile, an air gap (not shown) may be formed in place of at least one of the second insulating layer 242 and the fourth insulating layer 252. When the air gap is formed, an insulating liner (not shown) having a desired and/or alternatively predetermined thickness may be formed between the air gap and the first memory cell 240 and/or between the air gap and the second memory cell 250.

In embodiments, a first spacer 244 may be arranged on a sidewall of the first phase change layer 247. The first spacer 244 may overlap the first phase change layer 247 in the first horizontal direction (X direction). The first spacer 244 may overlap the first phase change layer 247 in the second horizontal direction (Y direction). Likewise, a second spacer 254 may be arranged on a sidewall of the second phase change layer 257. The second spacer 254 may overlap the second phase change layer 257 in the first horizontal direction (X direction) and the second horizontal direction (Y direction).

In the memory device 200 according to this embodiment, the first phase change layer 247 may include a γ-GeSe layer produced by the γ-GeSe layer manufacturing method (S10 and S10A) according to an embodiment described with reference to FIGS. 1 to 3. Although not shown in FIG. 16, the base layer 11 described in FIG. 3 may be formed between the intermediate electrode 145 and the phase change layer 147 and the phase change 147 may include a γ-GeSe layer produced by the γ-GeSe layer manufacturing method (S10 and S10A) according to an embodiment described with reference to FIGS. 1 to 3. Also, the base layer 11 described in FIG. 3 may be formed between the intermediate electrode 255 and the phase change layer 257 and the phase change 257 may include a γ-GeSe layer produced by the γ-GeSe layer manufacturing method (S10 and S10A) according to an embodiment described with reference to FIGS. 1 to 3.

The memory device 200 of the present embodiment may basically have a structure in which the memory device 100 having the structure described in FIGS. 14 and 15 is repeatedly stacked. However, the structure of the memory device 200 according to the present embodiment is not limited thereto.

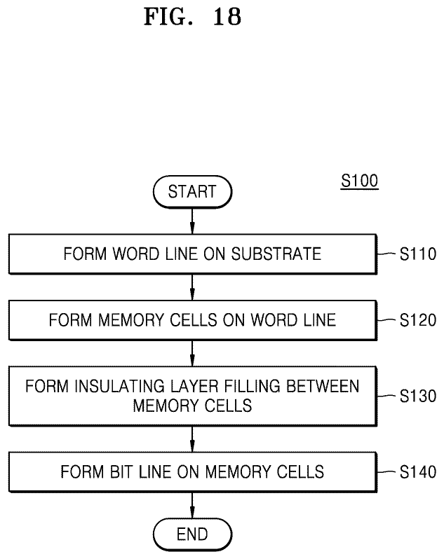

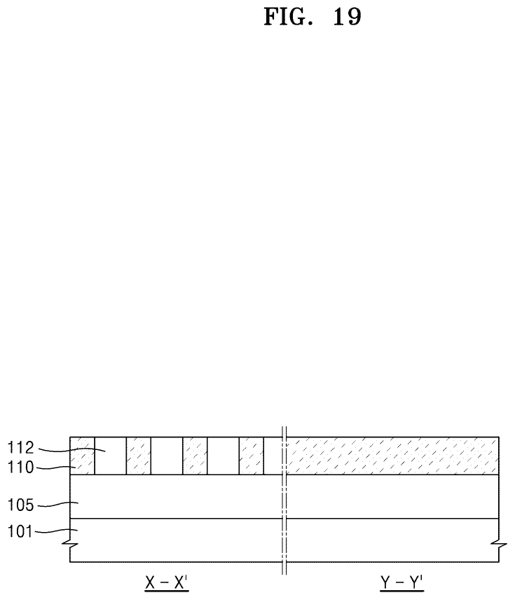

FIG. 18 is a flowchart illustrating a method of manufacturing a memory device (S100) according to an embodiment. FIGS. 19 to 21 are cross-sectional views showing a method of manufacturing a memory device according to an embodiment.

Referring to FIGS. 18 and 19, an operation S110 of forming a word line on a substrate may be performed.

Specifically, the interlayer insulating layer 105 is formed on the substrate 101. The interlayer insulating layer 105 may include, for example, silicon oxide or silicon nitride. The plurality of first conductive lines 110 extending in the first horizontal direction (X direction) and spaced apart from each other are formed on the interlayer insulating layer 105. The first conductive lines 110 may be formed by an embossed etching process or a damascene process. The first insulating layer 112 extending in the first horizontal direction (X direction) may be arranged between the first conductive lines 110. As described above, the first conductive lines 110 may correspond to the word line.

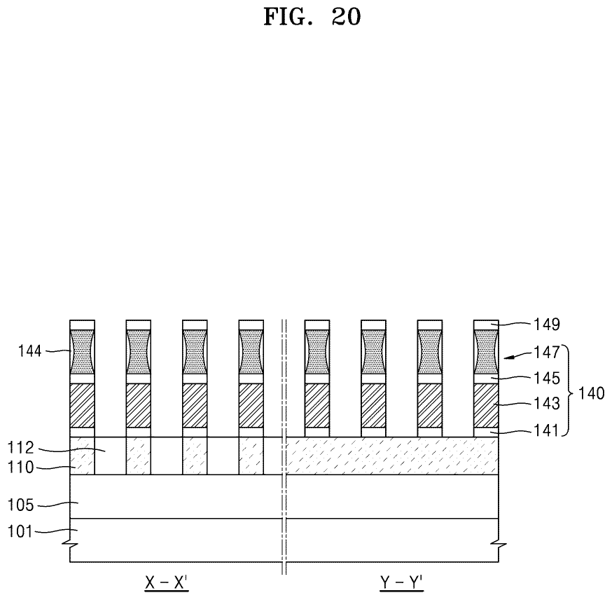

Referring to FIGS. 18 and 20, an operation S120 of forming memory cells on the word line may be performed.

Specifically, after sequentially stacking a lower electrode material, a switch layer material, an intermediate electrode material, a phase change layer material, and an upper electrode material on the first conductive line 110 and the first insulating layer 112, and etching the lower electrode material, the switch layer material, the intermediate electrode material, the phase change layer material, and the upper electrode material using an etch mask, a memory cell 140 including a lower electrode 141, a switch layer 143, a middle electrode 145, a phase change layer 147, and an upper electrode 149 may be formed. Thereafter, a spacer 144 may be further formed on the sidewall of the phase change layer 147.

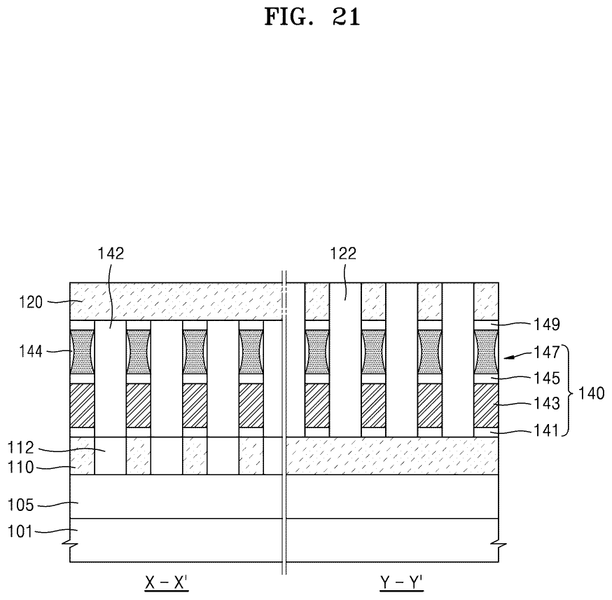

Referring to FIGS. 18 and 21, an operation S130 of forming an insulating layer filling between the memory cells and an operation S140 of forming a bit line on the memory cells may be performed.

Specifically, the second insulating layer 142 filling a space between the memory cells 140 may be formed. The second insulating layer 142 may include silicon oxide or silicon nitride that is the same as or different from that of the first insulating layer 112. The insulating material layer is formed to have a sufficient thickness to completely fill the space between the memory cells 140, and is planarized through a chemical mechanical polishing (CMP) process or the like to expose a top surface of the upper electrode 149, thereby forming the second insulating layer 142.

Next, a conductive layer for the second conductive line is formed and patterned through etching, thereby forming a plurality of second conductive lines 120. The plurality of second conductive lines 120 may extend in the second horizontal direction (Y direction) and may be spaced apart from each other. The third insulating layer 122 extending in the second horizontal direction (Y direction) may be arranged between the plurality of second conductive lines 120.

By the method S100 of manufacturing the memory device described with reference to FIGS. 18 to 21, the memory device 100 including, as a phase change layer, a γ-GeSe layer manufactured by the γ-GeSe layer manufacturing method (S10 and S10A) described with reference to FIGS. 1 to 3 may be manufactured.

That is, according to the present embodiment of inventive concepts, the method S100 of manufacturing a memory device with improved efficiency may be provided.

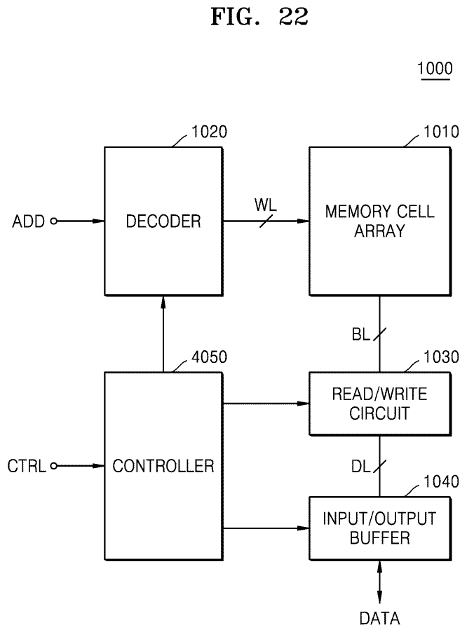

FIG. 22 is a block diagram of a memory system including a memory device manufactured by a method of manufacturing a memory device according to an embodiment.

Referring to FIG. 22, a memory system 1000 may include a memory cell array 1010, a decoder 1020, a read/write circuit 1030, an input/output buffer 1040, and a controller 1050. The memory cell array 1010 may include the memory devices 100 and 200 described above with reference to FIGS. 13 to 17.

A plurality of memory cells in the memory cell array 1010 may be coupled to the decoder 1020 through a word line WL, and may be coupled to the read/write circuit 1030 through a bit line BL. The decoder 1020 may receive an external address ADD and decode a row address and a column address to be accessed in the memory cell array 1010 under the control of the controller 1050 operating according to a control signal CTRL.

The read/write circuit 1030 may receive data from the input/output buffer 1040 through a data line DL, write data to a selected memory cell of the memory cell array 1010 under the control of the controller 1050, or provide, to the input/output buffer 1040, data read from a selected memory cell of the memory cell array 1010 under the control of the controller 1050.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A method of manufacturing a gamma-germanium selenide (γ-GeSe) layer, the method comprising:
coating a first surface of a base layer with a catalytic metal;
providing alpha-germanium selenide (α-GeSe) at a first position in a processing space, and providing the base layer at a second position in the processing space, the second position in the processing space being spaced apart from the first position in the processing space;
heating the first position in the processing space to a first temperature;
supplying gas from the first position in the processing space to the second position in the processing space; and
depositing γ-GeSe on the first surface of the base layer, wherein
the base layer includes a crystalline material having a crystal system that is hexagonal.

2. The method of claim 1, wherein the crystalline material in the base layer forms a superlattice with the γ-GeSe.

3. The method of claim 1, wherein the crystalline material in the base layer is hexagonal boron nitride or graphene.

4. The method of claim 1, wherein a ratio of a lattice parameter of the crystalline material in the base layer to a lattice parameter of the γ-GeSe is 2:3.

5. The method of claim 1, wherein in the depositing the γ-GeSe, the crystalline material included in the base layer does not react with the γ-GeSe.

6. The method of claim 1, wherein
in the heating the first position in the processing space to the first temperature, the second position is heated to a second temperature, and
the second temperature is lower than the first temperature.

7. The method of claim 6, wherein
the first temperature is 400° C. to 600° C., and
the second temperature is 300° C. to 400° C.

8. The method of claim 1, wherein the catalytic metal is gold (Au).

9. The method of claim 1, wherein the gas is an inert gas or nitrogen gas.

10. A method of manufacturing a gamma-germanium selenide (γ-GeSe) layer, the method comprising:
coating a first surface of a base layer with a catalytic metal;
providing alpha phase GeSe at a first position in a processing space and providing the base layer at a second position in the processing space, the second position of the processing space being spaced apart from the first position in the processing space;
vaporizing the alpha phase GeSe into vaporized GeSe by heating the first position of the processing space to a first temperature;
supplying the vaporized GeSe from the first position in the processing space to the second position in the processing space; and
depositing gamma-phase GeSe on the first surface of the base layer, wherein
a crystal system of the gamma-phase GeSe is same as a crystal system of a crystalline material in the base layer.

11. The method of claim 10, wherein the crystal system of the crystalline material in the base layer is hexagonal.

12. The method of claim 11, wherein the crystalline material in the base layer is hexagonal boron nitride or graphene.

13. The method of claim 10, wherein the crystalline material in the base layer forms a superlattice with the gamma-phase GeSe.

14. The method of claim 10, wherein, when the vaporizing the alpha phase GeSe is performed, the second position of the processing space is heated to a second temperature and the second temperature is lower than the first temperature.

15. The method of claim 10, wherein the depositing the gamma-phase GeSe comprises:
dissolving the vaporized GeSe in the catalytic metal; and
forming the gamma-phase GeSe on the first surface of the base layer with the dissolved GeSe.

16. The method of claim 10, wherein the depositing the gamma-phase GeSe comprises epitaxially growing the gamma-phase GeSe on the first surface of the base layer.

17. A method of manufacturing a memory device, the method comprising:
forming word lines on a substrate;
forming memory cells on the word lines;
forming an insulating layer between the memory cells;
and forming a bit line on each of the memory cells, wherein
each of the memory cells includes a lower electrode, a switch layer, an intermediate electrode, a phase change layer, and an upper electrode, which are sequentially stacked,
the phase change layer includes a gamma-GeSe (γ-GeSe) layer,
the forming the memory cells on the word lines includes forming the γ-GeSe layer through a process including
coating a first surface of a base layer with a catalytic metal,
providing alpha-GeSe (α-GeSe) at a first position in a processing space and providing the base layer at a second position in the processing space, the second position in the processing space being spaced apart from the first position in the processing space,
heating the first position in the processing space to a first temperature and heating the second position in the processing space to a second temperature, the second temperature being lower than the first temperature,
supplying gas from the first position in the processing space to the second position in the processing space, and
depositing γ-GeSe on the first surface of the base layer, wherein
the base layer includes a crystalline material having a crystal system that is hexagonal.

18. The method of claim 17, wherein the crystalline material in the base layer forms a superlattice with the γ-GeSe.

19. The method of claim 17, wherein the crystalline material in the base layer is hexagonal boron nitride or graphene.

20. The method of claim 17, wherein a ratio of a lattice parameter of the crystalline material included in the base layer to a lattice parameter of the γ-GeSe is 2:3.
